(19) United States
(12) Patent Application Publication
(10) Pub. No.: US 2006/0215368 A1
(43) Pub. Date: Sep. 28, 2006

(54) Heat-dissipating module and electronic apparatus having the same

(76) Inventor: Kuo-Ying Tsai, Hsin-Tien City (TW)

Correspondence Address: J C PATENTS, INC., 4 VENTURE, SUITE 250, IRVINE, CA, 92618, US

(21) Appl. No.: 11/148,863

(22) Filed: Jun. 8, 2005

(30) Foreign Application Priority Data
Mar. 28, 2005 (TW) 94109527

(51) Int. Cl. H05K 7/20

(52) U.S. Cl. 361/704; 361/720

(57) ABSTRACT

A heat dissipating module suitable for being disposed between a first fixed heat spreader and a second fixed heat spreader is provided. The heat dissipating module includes a first heat pipe, a second heat pipe, and a thermal conductive block. One end of the first heat pipe is connected with the first heat spreader. One end of the second heat pipe is connected with the second heat spreader. The thermal conductive block connects the other end of the first heat pipe with the other end of the second heat pipe.

### CROSS-REFERENCE TO RELATED APPLICATION

This application claims the priority benefit of Taiwan application serial no. 94109527, filed on Mar. 28, 2005. All disclosure of the Taiwan application is incorporated herein by reference.

### BACKGROUND OF THE INVENTION

1. Field of Invention

The present invention relates to an electronic apparatus and heat-dissipating module. More particularly, the present invention relates to an electronic apparatus and heat-dissipating module applying heat pipes and a thermal conductive block simultaneously.

2. Description of Related Art

Recently, as the continuous increase of the integration in the internal circuitry of the IC (Integrated Circuit) chip, the heat generated by the chip also increases. While the personal computer is operating, all the highly integrated IC chip, such as CPUs or graphic chips, may create heat. In order for the chip to operate normally in the long run, IC chip must be kept at a preferred working temperature to avoid declining performance or damage due to the over-high temperature. However, as the heat created in IC chip continuously increasing, the requirement of the heat spreading system also increases.

FIG. 1 is a cross-sectional view of a conventional electronic apparatus. Referring to FIG. 1, the conventional electronic apparatus includes a case 110, a motherboard 120, at least an electronic component 130, a heat spreader 140, a heat spreader 150, a thermal conductive block 160, and a heat sink 170, wherein the motherboard 120 is disposed inside the case 110, and the electronic component 130 is disposed on the surface of the motherboard 120. The heat spreader 140 is disposed on the electronic component 130 and in contact with the electronic component 130, and the heat spreader 150 is disposed on the inner wall of the case 110 and above the heat spreader 140. The thermal conductive block 160 is disposed between the heat spreaders 140 and 150, and in contact with both of them. The heat sink 170 is disposed on the case 110, and the heat spreader 150 is disposed between the heat sink 170 and the thermal conductive block 160.

The heat generated by the electronic component 130 can be transmitted to the outside via the heat spreader 140, the thermal conductive block 160, the heat spreader 150, the case 110 and the heat sink 170 in sequence. However, in the condition of fixed distance D between the heat spreaders 150 and 140, the thermal expansion of the thermal conductive block 160 not only results in thermal stress, but the manufacturing precision of the thermal conductive block 160 needs additional control. Additionally, the size and the weight of the thermal conductive block 160 would increase along with the increase of the distance D between the heat spreaders 150 and 140, and the thermal conductive blocks 160 with different specifications can not substitute each other as distances D are different. Moreover, compared with the heat pipe, the thermal conductivity of the thermal conductive block 160 is not so high (for example, 380 W/m° C.), so that heat pipe is used to replace the thermal conductive block 160.

FIG. 2 is a cross-sectional view of another conventional electronic apparatus. Please refer to FIG. 2, the conventional electronic apparatus 200 is similar to the conventional electronic apparatus 100, and the difference is that in the conventional electronic apparatus 200, the heat pipe 210 is connected with the heat spreaders 140 and 150, so that the heat generated by the electronic component 130 can be transmitted to the outside via the heat spreader 140, the heat pipe 210, the heat spreader 150, the case 110 and the heat sink 170 in sequence. Compared with the thermal conductive block 160, the heat pipe 210 is not only lighter, but also has high thermal conductivity (for example, 40,000 W/m° C.). However, the heat pipe 210 not only has the minimum turning radius limit, but also has higher cost than the thermal conductive block 160. Also, the heat pipes 210 with different specification can not substitute each other as distances D are different.

### SUMMARY OF THE INVENTION

Accordingly, the present invention is directed to a heat dissipating module which is convenient in assembling.

Moreover, the present invention is directed to another heat dissipating module with lighter weight.

Additionally, the present invention is directed to an electronic apparatus with better heat-spreading efficiency.

According to the above and other objects, the present invention provides a heat dissipating module suitable for being disposed between a first fixed heat spreader and a second fixed heat spreader. The heat dissipating module includes a first heat pipe, a second heat pipe, and a thermal conductive block, wherein one end of the first heat pipe is connected with the first heat spreader. One end of the second heat pipe is connected with the second heat spreader. The thermal conductive block is used to connect the other end of the first heat pipe with the other end of the second heat pipe.

According to the above and other objects, the present invention provides a heat dissipating module suitable for being disposed between a first fixed heat spreader and a second fixed heat spreader. The heat dissipating module includes a plurality of heat pipes, and a plurality of thermal conductive blocks. One end of the heat pipe closest to the first heat spreader is connected with the first heat spreader, and one end of the heat pipe closest to the second heat spreader is connected with the second heat spreader. Additionally, the two adjacent heat pipes are connected with each other by one of the corresponding thermal conductive blocks.

According to the above and other objects, the present invention provides an electronic apparatus which includes a case, a motherboard, at least an electronic component, a first heat spreader, a second heat spreader and a heat dissipating module, wherein the motherboard is disposed inside the case, and the electronic component is disposed on the surface of the motherboard. The first heat spreader is disposed on the electronic component, and the second heat spreader is disposed on the inner wall of the case. The heat dissipating module is disposed between the first heat spreader and the second heat spreader, and the heat dissipating module includes a plurality of heat pipes, and at least one thermal conductive block. One end of the heat pipe closest to the first heat spreader is connected with the first heat spreader, and one end of the heat pipe closest to the second heat spreader is connected with the second heat spreader. Additionally, the two adjacent heat pipes are connected with each other by the corresponding thermal conductive block.

According to the above description, the present invention provides a heat dissipating module applying the combination of the thermal conductive blocks and heat pipes, so that the heat dissipating module of the present invention is easy to be assembled between the two fixed heat spreaders. Additionally, the number of the thermal conductive blocks and heat pipes in the heat dissipating module of the present invention can be adjusted according to the different distance between the two fixed heat spreaders, so that the heat dissipating module of the present invention can meet the requirement of different specifications.

In order to the make the aforementioned and other objects, features and advantages of the present invention comprehensible, a preferred embodiment accompanied with figures is described in detail below.

### BRIEF DESCRIPTION OF THE DRAWINGS

FIG. 1 is a cross-sectional view of a conventional electronic apparatus.

FIG. 2 is a cross-sectional view of another conventional electronic apparatus.

FIG. 3 is a cross-sectional view of the heat dissipating module applied in an electronic apparatus according to the first embodiment of the present invention.

FIG. 4 is a cross-sectional view of the heat dissipating module according to the second embodiment of the present invention.

### DESCRIPTION OF EMBODIMENTS

### The First Embodiment

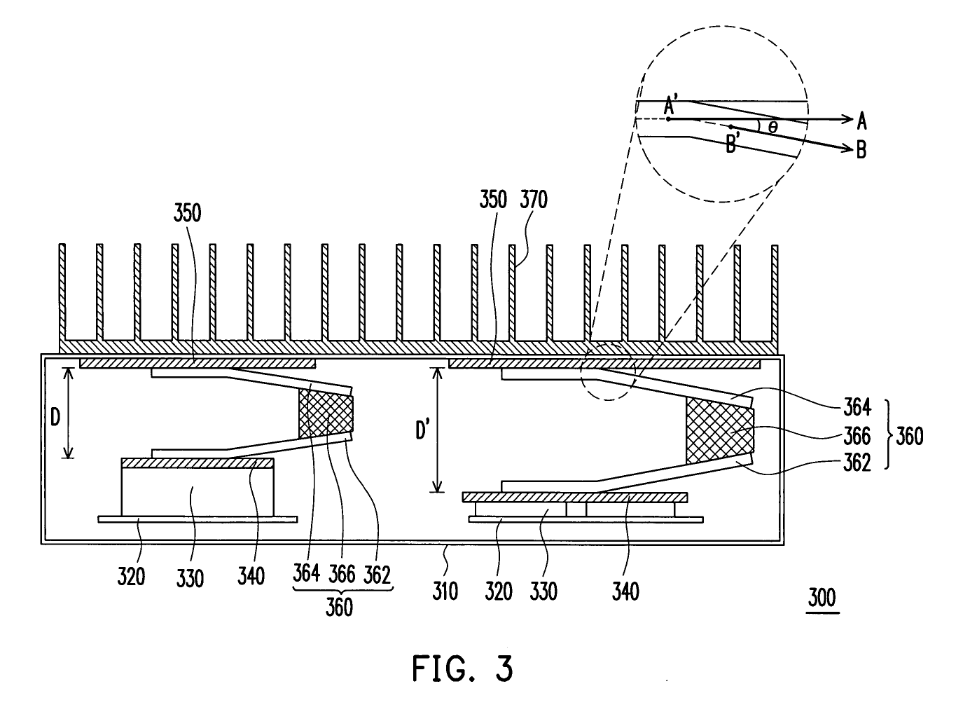

FIG. 3 is a cross-sectional view of the heat dissipating module applied in an electronic apparatus according to the first embodiment of the present invention. Referring to FIG. 3, the electronic apparatus 300 of the embodiment includes a case 310, a motherboard 320, at least an electronic component 330, a heat spreader 340, a heat spreader 350, and a heat dissipating module 360, wherein the motherboard 320 is disposed inside the case 310, and the electronic component 330 is disposed on the surface of the motherboard 320. Additionally, the electronic component 330 can be, for example, Central Processor Unit (CPU), chip set, graphic chip or other electronic components which create heat.

The heat spreader 340 is disposed on the electronic component 330 so that the heat generated by the electronic component 330 can be transmitted to the heat spreader 340. However, a gap-filler layer (not shown) can be disposed between the heat spreader 340 and the electronic component 330 in order to improve the heat transmission efficiency. Moreover, the heat spreader 350 is disposed on the inner wall of the case 310, and the gap-filler layer (not shown) can be disposed between the heat spreader 350 and the case 310 to improve the heat transmission efficiency. Moreover, the heat dissipating module 360 is disposed between the fixed heat spreaders 340 and 350, so that the heat generated by the electronic component 330 can be transmitted to the heat spreader 350 via the heat spreader 340 and the heat dissipating module 360 in sequence.

In more detail, the heat dissipating module 360 includes a heat pipe 362, a heat pipe 364 and a thermal conductive block 366, wherein one end of the heat pipe 362 is connected with one end of the heat pipe 364 by the thermal conductive block 366, and the connection method can be by welding or latching. Additionally, the other end of the heat pipe 362 can be connected with the heat spreader 340 by welding or latching, and the other end of the heat pipe 364 can be connected with the heat spreader 350 by welding or latching. In other words, the heat generated by the electronic component 330 can be transmitted to the heat spreader 350 via the heat spreader 340, the heat pipe 362, the thermal conductive block 366 and the heat pipe 364. Additionally, the electronic apparatus 300 can also have a heat sink 370 disposed on the case 310 in order to improve the heat transmission efficiency, and the heat spreader 350 is disposed between the heat sink 370 and the heat pipe 364.

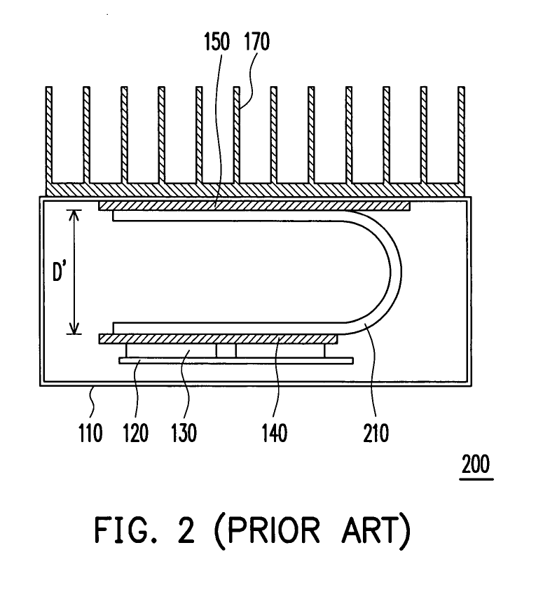

Please refer to the enlarged area in FIG. 3, in order for the working liquid in the heat pipes 362 and 364 to flow smoothly, the turning angle of the heat pipes 362 and 364 can not be too large. That is, the shape of the heat pipes 362 and 364 is not similar with the heat pipe 210 in FIG. 2. In more detail, the angle of the two tangent vectors at any two points on the axis of the heat pipe 362 can be smaller than 180 degree. Moreover, the angle of the two tangent lines at any two points on the axis of the heat pipe 364 can be smaller than 180 degree. For example, select two points A′ and B′ on the axis of the heat pipe 364, and the angle θ formed by the tangent vector A at A′ point and the tangent vector B at B′ point must be smaller than 180 degree.

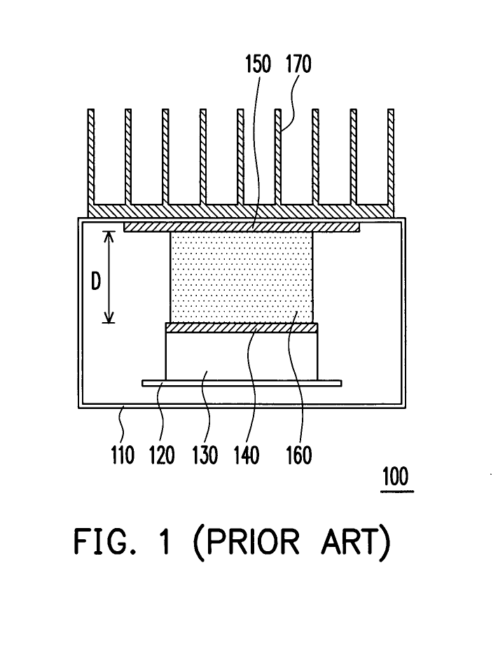

Compared with the conventional technology shown in FIG. 1, as the heat pipes 364 and 362 can be deformed, the heat dissipating module 360 of the embodiment can be not only suitable for distance D′ (as shown in the right side in FIG. 3), but also for distance D (as shown in the left side in FIG. 3). That is, the heat dissipating module 360 of the embodiment has larger application range, and also is easy to be assembled inside the electronic apparatus 300. Moreover, compared with the thermal conductive block in the conventional technology (as shown in FIG. 1), the heat dissipating module 360 of the embodiment has lighter weight and better heat transmission efficiency. Compared with the heat pipe in the conventional technology (as shown in FIG. 2), the heat dissipating module 360 of the embodiment can be suitable for smaller distance D, and the heat pipes 364 and 362 of the heat dissipating module 360 can be products with standard specification to reduce the product cost of the heat dissipating module 360.

### The Second Embodiment

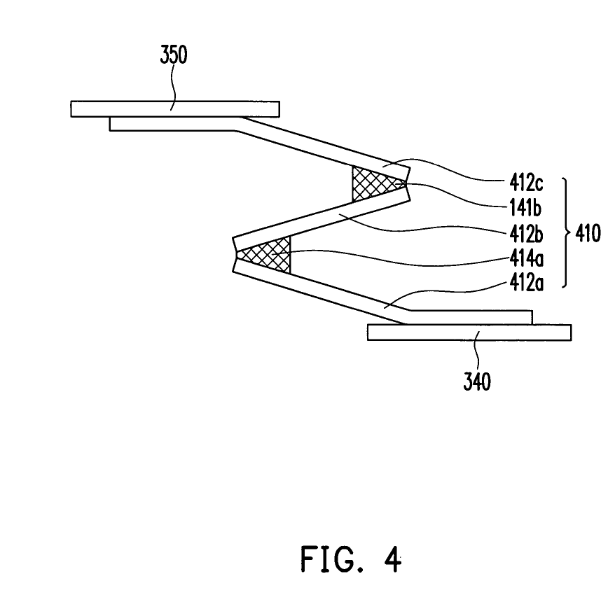

FIG. 4 is a cross-sectional view of the heat dissipating module according to the second embodiment of the present invention. Referring to FIG. 4, the second embodiment is similar to the first embodiment, and the difference is that if the distance between the heat spreaders 350 and 340 is long, the heat dissipating module 410 has a plurality of heat pipes 412a, 412b, 412c and a plurality of thermal conductive blocks 414a, 414b, wherein one end of the heat pipe 412a is welded or latched to the fixed heat spreader 340, and one end of the heat pipe 412c is welded or latched to the fixed heat spreader 350.

The thermal conductive block 414a can connect the two adjacent heat pipes 412a with 412b by, for example, welding or latching, and the thermal conductive block 414b can connect the two adjacent heat pipes 412b with 412c by, for example, welding or latching. Moreover, as the same as the first embodiment, in order for the working liquid to flow easily, the angle of the two tangent vectors at any two points on the axis of each heat pipe may be smaller than 180 degree.

The number of the thermal conductive blocks and the heat pipes of the heat dissipating module 410 can be adjusted along with the different distance D between the heat spreaders 350 and 340. Moreover, the heat spreaders 350 and 340 can be overlapped (as shown in FIG. 3) or not (as shown in FIG. 4). That is, the embodiment is not limited to the relative positions of the heat spreaders 350 and 340, but there must be some distance between the heat spreaders 350 and 340 to contain the heat dissipating module 410.

In summary, the electronic apparatus and the heat dissipating module according to the present invention have at least the following advantages.

1. Compared with the thermal conductive blocks in the conventional technology, as the heat pipes of the heat dissipating module in the present invention can be deformed properly, thus can be easily assembled between two fixed heat spreaders.

2. Compared with the thermal conductive block in the conventional technology, the heat dissipating module of the present invention has less weight and better heat transmission efficiency.

3. Compared with the limit of minimum turning radius when using the heat pipe in the conventional technology, the heat dissipating module of the present invention does not have the limit of the minimum turning radius, and can adopt products with standard specification to reduce the product cost of the heat dissipating module.

4. The number of the thermal conductive blocks and the heat pipes of the heat dissipating module of the present invention can be adjusted along with the different distance D between the fixed heat spreaders to meet the design specification.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat dissipating module suitable for being disposed between a first fixed heat spreader and a second fixed heat spreader, the heat dissipating module comprising:
a first heat pipe, one end of which connected with the first heat spreader;
a second heat pipe, one end of which connected with the second heat spreader; and
a thermal conductive block, connecting the other end of the first heat pipe with the other end of the second heat pipe.

2. The heat dissipating module as claimed in claim 1, wherein an angle of two tangent vectors at any two points on an axis of the first heat pipe is smaller than 180 degree.

3. The heat dissipating module as claimed in claim 1, wherein an angle of two tangent vectors at any two points on the axis of the second heat pipe is smaller than 180 degree.

4. The heat dissipating module as claimed in claim 1, wherein a method for the thermal conductive block to connect the other end of the first heat pipe with the other end of the second heat pipe comprises welding or latching.

5. The heat dissipating module as claimed in claim 1, wherein the end of the first heat pipe is connected with the first heat spreader by a welding method.

6. The heat dissipating module as claimed in claim 1, wherein the end of the second heat pipe is connected with the second heat spreader by a welding method.

7. A heat dissipating module suitable for being disposed between a first fixed heat spreader and a second fixed heat spreader, the heat dissipating module comprising:
a plurality of heat pipes, wherein one end of the heat pipe closest to the first heat spreader is connected with the first heat spreader, and one end of the heat pipe closest to the second heat spreader is connected with the second heat spreader; and
a plurality of thermal conductive blocks, wherein two adjacent heat pipes are connected with each other by one of the corresponding thermal conductive blocks.

8. The heat dissipating module as claimed in claim 7, wherein an angle of the two tangent vectors at any two points on the axis of each heat pipe is smaller than 180 degree.

9. The heat dissipating module as claimed in claim 7, wherein a method for connecting two adjacent heat pipes with each other by one of the responding thermal conductive blocks comprises welding or latching.

10. The heat dissipating module as claimed in claim 7, wherein the end of the heat pipe closest to the first heat spreader is connected with the first heat spreader by a welding method.

11. The heat dissipating module as claimed in claim 7, wherein the end of the heat pipe closest to the second heat spreader is connected with the second heat spreader by a welding method.

12. An electronic apparatus, comprising:
a case;
a motherboard disposed inside the case;
at least an electronic component disposed on a surface of the motherboard;
a first heat spreader disposed on the electronic component;
a second heat spreader disposed on the inner wall of the case;
a heat dissipating module disposed between the first heat spreader and the second heat spreader, the heat dissipating module comprising:
a plurality of heat pipes, wherein one end of the heat pipe closest to the first heat spreader is connected with the first heat spreader, and one end of the heat pipe closest to the second heat spreader is connected with the second heat spreader; and
at least one conductive block, wherein two adjacent heat pipes are connected with each other by the corresponding thermal conductive block.

13. The electronic apparatus as claimed in claim 12, wherein an angle of two. tangent vectors at any two points on the axis of each heat pipe is smaller than 180 degree.

14. The electronic apparatus as claimed in claim 12, wherein the method for connecting two adjacent heat pipes with each other by the responding thermal conductive block comprises welding or latching.

15. The electronic apparatus as claimed in claim 12, wherein the end of the heat pipe closest to the first heat spreader is connected with the first heat spreader by a welding method.

16. The electronic apparatus as claimed in claim 12, wherein the end of the heat pipe closest to the second heat spreader is connected with the second heat spreader by a welding method.

17. The electronic apparatus as claimed in claim 12, further comprising a heat sink disposed on the case, the second heat spreader being disposed between the heat sink and the second heat pipe.
